(19) United States
(12) Patent Application Publication
(10) Pub. No.: US 2026/0371845 A1
(43) Pub. Date: Nov. 19, 2026

(54) DISPLAY DEVICE

(71) Applicant: Sharp Display Technology Corporation, Kameyama City, Mie (JP)

(72) Inventor: Tadayoshi MIYAMOTO, Kameyama City, Mie (JP)

(21) Appl. No.: 19/154,151

(22) PCT Filed: Feb. 10, 2023
(86) PCT No.: PCT/JP2023/004625

§ 371 Date: Aug. 6, 2025

(51) Int. Cl. H10K 59/121; G09G 3/3233; H10K 59/131

(52) U.S. Cl. CPC H10K 59/1213; H10K 59/131; G09G 3/3233; G09G 2300/0426

(57) ABSTRACT

A display device includes a thin-film transistor layer provided on a base substrate. The thin-film transistor layer includes a first metal film, a first inorganic insulating film, a first semiconductor film made of polysilicon, a second inorganic insulating film, a second metal film, a third inorganic insulating film, a third metal film, a second semiconductor film made of oxide semiconductor, a fourth inorganic insulating film, and a fourth metal film. The thin-film transistor layer includes a second thin-film transistor having a second semiconductor layer. The second thin-film transistor includes a third terminal electrode and a fourth terminal electrode. The third terminal electrode and the fourth terminal electrode are electrically connected respectively to a third conductor region and a fourth conductor region of the second semiconductor layer. A display region is provided with a plurality of wires formed of the first metal film and extending in parallel with one another.

### TECHNICAL FIELD

The present disclosure relates to a display device.

### BACKGROUND ART

In recent years, light-emitting organic electroluminescence (EL) display devices using organic EL elements have attracted attention as a replacement for liquid crystal display devices. An organic EL display device is provided with a plurality of thin-film transistors (hereinafter also referred to as “TFTs”) for each of subpixels. A subpixel is a minimum unit of an image. Here, examples of a well-known semiconductor layer for a TFT include: a semiconductor layer made of polysilicon having high mobility; and a semiconductor layer made of oxide semiconductor such as In—Ga—Zn—O and exhibiting low current leakage.

For example, Patent Document 1 discloses a display device having a hybrid structure in which a first TFT made of polysilicon semiconductor and a second TFT made of oxide semiconductor are formed on a substrate.

### CITATION LIST

### Patent Literature

[Patent Document 1] Japanese Unexamined Patent Application Publication No. 2020-017558

### SUMMARY

### Technical Problems

As to the hybrid display device disclosed in Patent Document 1, the semiconductor layer made of oxide semiconductor has electrical connection through a metal layer in contact with the semiconductor layer. Such a configuration makes it possible to form contact holes at once for the electrical connection to each of the semiconductor layer made of polysilicon semiconductor and the semiconductor layer made of oxide semiconductor, and to readily establish the electrical connection to the semiconductor layer made of oxide semiconductor. However, the hybrid display device disclosed in the above Patent Document 1 is likely to exhibit large wiring cross capacitance observed at an intersection of a wire (e.g., a gate line) formed of the same material as, and in the same layer as, a gate electrode of the second TFT formed of oxide semiconductor and a wire (e.g., a source line) formed of the same material as, and in the same layer, as, a source electrode and a drain electrode of the second TFT. Such a hybrid display device has room for improvement.

The present disclosure is conceived in view of the above problem, and sets out to readily establish electrical connection to a semiconductor layer made of oxide semiconductor, and, simultaneously, to reduce wiring cross capacitance.

### Solution to Problem

In order to achieve the above object, a display device according to the present disclosure includes: a base substrate; and a thin-film transistor layer provided on the base substrate and including: a first metal film; a first inorganic insulating film; a first semiconductor film made of polysilicon; a second inorganic insulating film; a second metal film; a third inorganic insulating film; a third metal film; a second semiconductor film made of oxide semiconductor; a fourth inorganic insulating film; and a fourth metal film, all of which are sequentially stacked on top of another. The thin-film transistor layer includes: a first thin-film transistor having a first semiconductor layer formed of the first semiconductor film; and a second thin-film transistor having a second semiconductor layer formed of the second semiconductor film. The first thin-film transistor and the second thin-film transistor are provided for each of subpixels included in a display region. The first thin-film transistor includes: the first semiconductor layer; a first gate electrode; and a first terminal electrode and a second terminal electrode. The first semiconductor layer includes: a first conductor region and a second conductor region defined to be spaced apart from each other; and a first channel region defined between the first conductor region and the second conductor region. The first gate electrode is formed of the second metal film and provided above the first semiconductor layer through the second inorganic insulating film, and the first terminal electrode and the second terminal electrode are formed of the third metal film, spaced apart from each other, and respectively and electrically connected to the first conductor region and the second conductor region.” The second thin-film transistor includes: the second semiconductor layer; a second gate electrode; and a third terminal electrode and a fourth terminal electrode. The second semiconductor layer includes: a third conductor region and a fourth conductor region defined to be spaced apart from each other; and a second channel region defined between the third conductor region and the fourth conductor region. The second gate electrode is formed of the fourth metal film and provided above the second semiconductor layer through the fourth inorganic insulating film, and the third terminal electrode and the fourth terminal electrode are formed of the third metal film, spaced apart from each other, and respectively and electrically connected to the third conductor region and the fourth conductor region. The display region is provided with a plurality of wires formed of the first metal film and extending in parallel with one another.

### Advantageous Effect of Disclosure

The present disclosure can readily establish electrical connection to a semiconductor layer made of oxide semiconductor, and simultaneously reduce wiring cross capacitance.

### BRIEF DESCRIPTION OF DRAWINGS

FIG. 1 is a plan view of a schematic configuration of an organic EL display device according to a first embodiment of the present disclosure.

FIG. 2 is a plan view of a display region of the organic EL display device according to the first embodiment of the present disclosure.

FIG. 3 is a cross-sectional view of the display region of the organic EL display device according to the first embodiment of the present disclosure.

FIG. 4 is an equivalent circuit diagram of a TFT layer included in the organic EL display device according to the first embodiment of the present disclosure.

FIG. 5 is a cross-sectional view of a light-emission control TFT 9f and an anode-discharge TFT 9g included in the TFT layer of the organic EL display device according to the first embodiment of the present disclosure.

FIG. 6 is a cross-sectional view of a write TFT 9c included in the TFT layer of the organic EL display device according to the first embodiment of the present disclosure.

FIG. 7 is a cross-sectional view of a power-supply TFT 9e included in the TFT layer of the organic EL display device according to the first embodiment of the present disclosure.

FIG. 8 is a cross-sectional view of an initialization TFT 9a included in the TFT layer of the organic EL display device according to the first embodiment of the present disclosure.

FIG. 9 is a cross-sectional view of an organic EL layer included in the organic EL display device according to the first embodiment of the present disclosure.

FIG. 10 is a cross-sectional view of the display region of an organic EL display device according to a second embodiment of the present disclosure.

### DESCRIPTION OF EMBODIMENTS

Embodiments of the present disclosure will be described in detail below with reference to the drawings. Note that the present disclosure shall not be limited to the embodiments below.

### First Embodiment

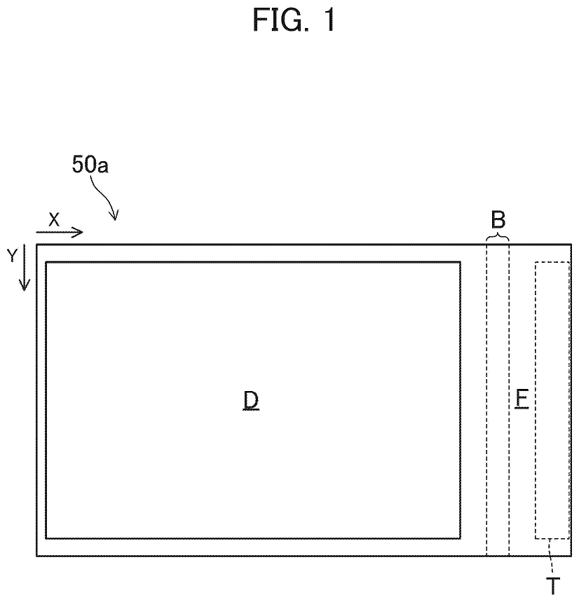

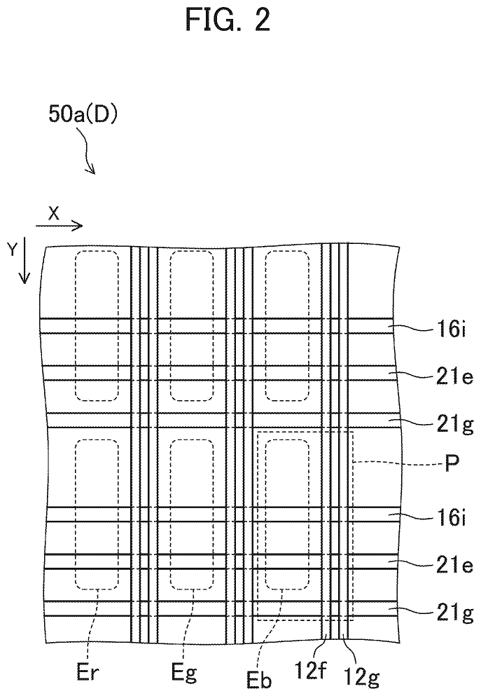

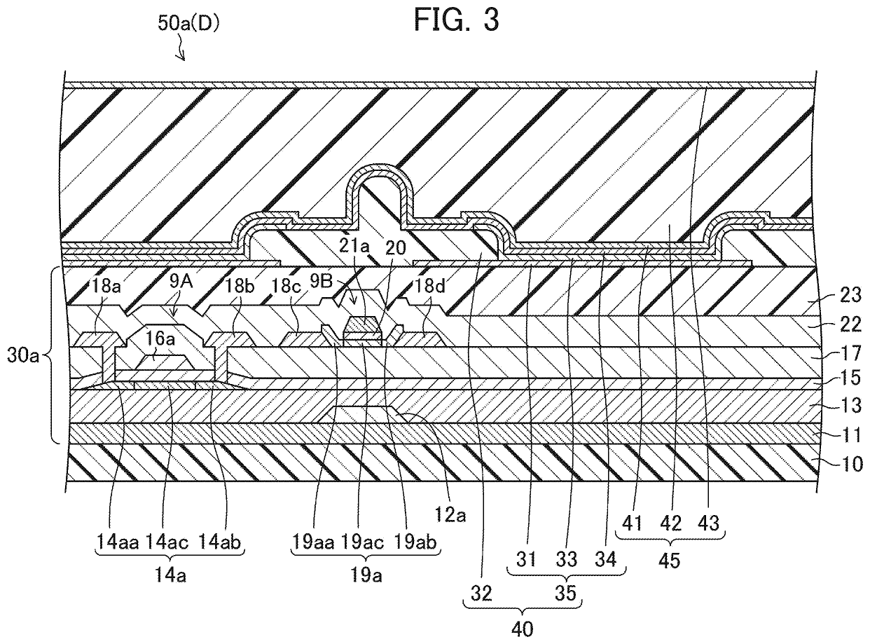

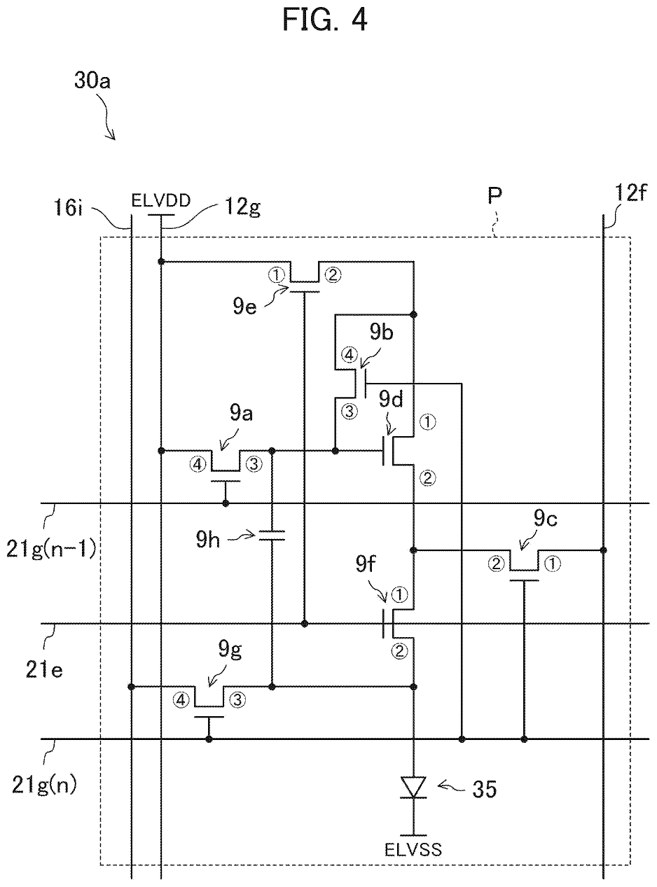

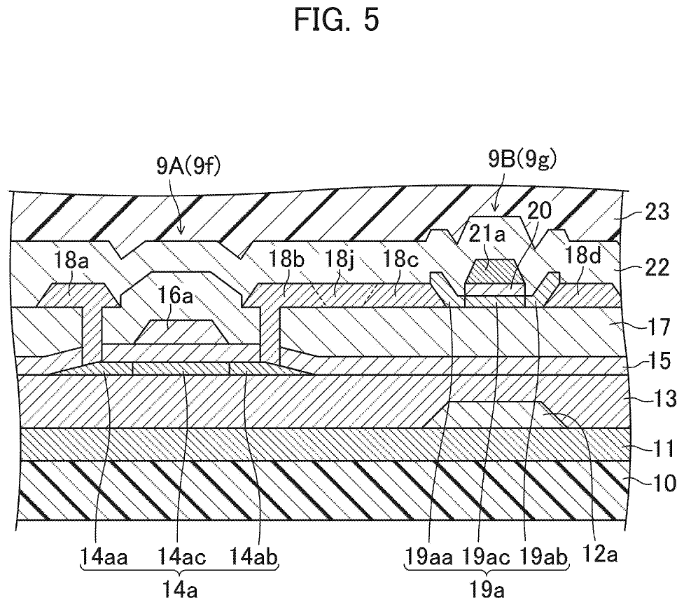

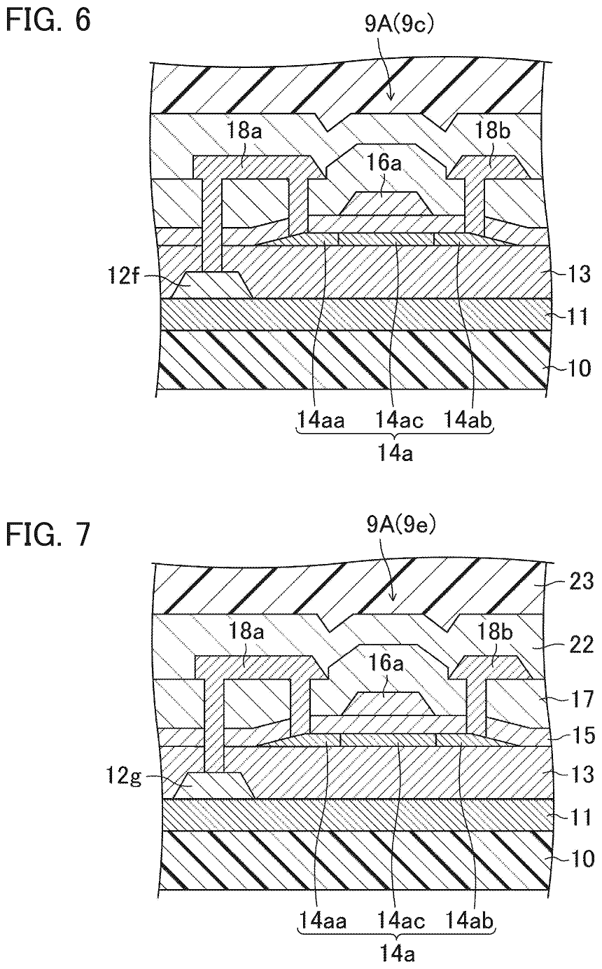

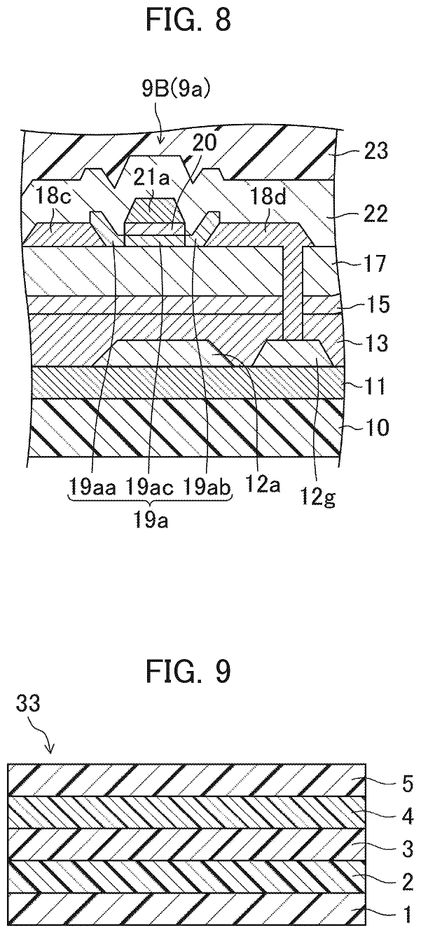

FIGS. 1 to 9 illustrate a first embodiment of a display device according to the present disclosure. Note that, in the embodiments below, an organic EL display device including an organic-EL-element layer is exemplified as a display device including a light-emitting-element layer. Here, FIG. 1 is a plan view of a schematic configuration of an organic EL display device 50a according to this embodiment. Furthermore, FIG. 2 and FIG. 3 are respectively a plan view and a cross-sectional view of a display region D of the organic EL display device 50a. FIG. 4 is an equivalent circuit diagram of a TFT layer 30a included in the organic EL display device 50a. FIG. 5 is a cross-sectional view of a light-emission control TFT 9f and an anode-discharge TFT 9g included in the TFT layer 30a. FIG. 6 is a cross-sectional view of a write TFT 9c included in the TFT layer 30a. FIG. 7 is a cross-sectional view of a power-supply TFT 9e included in the TFT layer 30a. FIG. 8 is a cross-sectional view of an initialization TFT 9a included in the TFT layer 30a. FIG. 9 is a cross-sectional view of an organic EL layer 33 included in the organic EL display device 50a.

As illustrated in FIG. 1, the organic EL display device 50a includes, for example: the display region D shaped into a rectangle and displaying an image; and a picture-frame region F provided around the display region D. Note that this embodiment exemplifies the display region D shaped into a rectangle. Examples of the rectangle include such substantial rectangles as a rectangle having arc-like sides, a rectangle having rounded corners, and a rectangle having partially notched sides.

The display region D illustrated in FIG. 2 includes a plurality of subpixels P arranged in a matrix. Moreover, in the display region D, as illustrated in FIG. 2, for example, subpixels P having red light-emitting regions Er for presenting red, subpixels P having green light-emitting regions Eg for presenting green, and subpixels P having blue light-emitting regions Eb for presenting blue are provided side by side. Note that, in the display region D, for example, neighboring three subpixels P each having one of a red light-emitting region Er, a green light-emitting region Eg, and a blue light-emitting region Eb constitute one pixel.

The picture-frame region F in FIG. 1 has an end portion in the positive X-direction. The end portion is provided with a terminal unit T extending in one direction (in a Y-direction in FIG. 1). Moreover, as illustrated in FIG. 1, the picture-frame region F includes, for example, a folding portion B between the display region D and the terminal unit T. The folding portion B, extending in one direction (in the Y-direction in the drawing), is foldable around a folding axis in the Y-direction in the drawing at an angle of 180° (foldable in a U-shape).

As illustrated in FIG. 3, the organic EL display device 50a includes: a resin substrate 10 provided as a base substrate; a TFT layer 30a provided on the resin substrate 10; an organic-EL-element layer 40 provided on the TFT layer 30a to serve as a light-emitting-element layer; and a sealing film 45 provided on the organic-EL-element layer 40.

The resin substrate 10 is made of, for example, an organic resin material such as polyimide resin.

The TFT layer 30a illustrated in FIG. 3 includes: a first base coat film 11 and a second base coat film 13 sequentially provided above the resin substrate 10; four first TFTs 9A, three second TFTs 9B, and one capacitor 9h all of which are provided on the second base coat film 13 for each of the subpixels P (see FIG. 4); and a second interlayer insulating film 22 and a planarization film 23 sequentially provided above each of the first TFTs 9A, the second TFTs 9B, and the capacitor 9h. Here, the TFT layer 30a includes, as illustrated in FIG. 2, a plurality of gate lines 21g extending in parallel with one another in the X-direction in the drawing. Furthermore, the TFT layer 30a includes, as illustrated in FIG. 2, a plurality of light-emission control lines 21e extending in parallel with one another in the X-direction in the drawing. Moreover, the TFT layer 30a includes, as illustrated in FIG. 2, a plurality of second initialization power supply lines 16i extending in parallel with one another in the X-direction in the drawing. Note that, as illustrated in FIG. 2, the light-emission control lines 21e are provided side by side with the gate lines 21g and the second initialization power supply lines 16i. In addition, the TFT layer 30a includes, as illustrated in FIG. 2, a plurality of source lines 12f extending in parallel with one another in the Y-direction in the drawing and provided to serve as a plurality of wires. In addition, the TFT layer 30a includes, as illustrated in FIG. 2, a plurality of power supply lines 12g extending in parallel with one another in the Y-direction in the drawing and provided to serve as a plurality of wires. Note that, as illustrated in FIG. 2, the power supply lines 12g and the source lines 12f are provided side by side.

The TFT layer 30a illustrated in FIG. 3 includes: the first base coat film 11; a first metal film; the second base coat film (a first inorganic insulating film) 13; a first semiconductor film; a first gate insulating film (a second inorganic insulating film) 15; a second metal film; a first interlayer insulating film (a third inorganic interlayer insulating film) 17; a third metal film; a second semiconductor film; a second gate insulating film (a fourth inorganic insulating film) 20; a fourth metal film; the second interlayer insulating film (a fifth inorganic insulating film) 22; and the planarization film 23, all of which are sequentially stacked on top of another above the resin substrate 10. Here, a source line 12f and a power supply line 12g are formed of the first metal film. Furthermore, a second initialization power supply line 16i is formed of the second metal film. Moreover, a gate line 21g and a light-emission control line 21e are formed of the fourth metal film. Note that this embodiment exemplifies a configuration in which the second initialization power supply line 16i is formed of the second metal film. Alternatively, the second initialization power supply line may be formed of the third metal film. Here, the second initialization power supply line 16i is farther spaced apart from the source line 12f and the power supply line 12g in the thickness direction in a case where the second initialization power supply line 16i is formed of the third metal film than in a case where the second initialization power supply line 16i is formed of the second metal film. Such a feature can reduce wiring cross capacitance between: the second initialization power supply line 16i; and the source line 12f and the power supply line 12g.

Each of the first base coat film 11, the second base coat film 13, the first gate insulating film 15, the first interlayer insulating film 17, the second gate insulating film 20, and the second interlayer insulating film 22 is an inorganic monolayer insulating film made of such a substance as, for example, silicon nitride, silicon oxide, or silicon oxynitride. Alternatively, each film is an inorganic multilayer insulating film made of these substances. Here, the first interlayer insulating film 17 and the second gate insulating film 20 have respective portions toward a second semiconductor layer 19a, and the portions are made of, for example, silicon oxide films.

As illustrated in FIG. 3, each of the first TFTs 9A includes: a first semiconductor layer 14a provided on the second base coat film 13; a first gate electrode 16a provided above the first semiconductor layer 14a through the first gate insulating film 15; and a first terminal electrode 18a and a second terminal electrode 18b provided on the first interlayer insulating film 17 and spaced apart from each other.

The first semiconductor layer 14a is formed of, for example, the first semiconductor film made of polysilicon such as low temperature polysilicon (LTPS). As illustrated in FIG. 3, the first semiconductor layer 14a includes: a first conductor region 14aa and a second conductor region 14ab defined to be spaced apart from each other; and a first channel region 14ac defined between the first conductor region 14aa and the second conductor region 14ab.

As illustrated in FIG. 3, the first gate electrode 16a is provided to overlap with the first channel region 14ac of the first semiconductor layer 14a. The first gate electrode 16a controls conduction between the first conductor region 14aa and the second conductor region 14ab of the first semiconductor layer 14a. Here, similar to the second initialization power supply line 16i, the first gate electrode 16a is formed of the second metal film.

As illustrated in FIG. 3, the first terminal electrode 18a and the second terminal electrode 18b are respectively and electrically connected to the first conductor region 14aa and the second conductor region 14ab of the first semiconductor layer 14a through contact holes formed in a multilayer film including the first gate insulating film 15 and the first interlayer insulating film 17. Here, the first terminal electrode 18a and the second terminal electrode 18b are formed of the third metal film.

As illustrated in FIG. 3, each of the second TFTs 9B includes: the second semiconductor layer 19a provided on the first interlayer insulating film 17; a second gate electrode 21a provided above the second semiconductor layer 19a through the second gate insulating film 20; and a third terminal electrode 18c and a fourth terminal electrode 18d provided on the first interlayer insulating film 17 and spaced apart from each other through the second semiconductor layer 19a.

The second semiconductor layer 19a is formed of the second semiconductor film made of, for example, an In—Ga—Zn—O-based oxide semiconductor. As illustrated in FIG. 3, the second semiconductor layer 19a includes: a third conductor region 19aa and a fourth conductor region 19ab defined to be spaced apart from each other; and a second channel region 19ac defined between the third conductor region 19aa and the fourth conductor region 19ab. Furthermore, as illustrated in FIG. 3, a lower light-blocking layer 12a formed of the first metal film is provided to the second semiconductor layer 19a toward the resin substrate 10. Note that the lower light-blocking layer 12a is provided to overlap with the second semiconductor layer 19a of the second TFT 9B in a plan view. Here, the In—Ga—Zn—O-based semiconductor is a ternary oxide of indium (In), gallium (Ga), and zinc (Zn), and a ratio (a composition ratio) of In to Ga to Zn shall not be limited to a particular ratio. Furthermore, the In—Ga—Zn—O-based semiconductor may be amorphous or crystalline. Note that the crystalline In—Ga—Zn—O-based semiconductor is preferably a crystalline In—Ga—Zn—O-based semiconductor in which the c-axis is oriented substantially perpendicular to the layer plane. Moreover, instead of the In—Ga—Zn—O-based semiconductor, the second semiconductor layer 19a may contain another oxide semiconductor. Examples of the other oxide semiconductor may include an In—Sn—Zn—O-based semiconductor (e.g., In₂O₃—SnO₂—ZnO; InSnZnO). Here, the In—Sn—Zn—O-based semiconductor is a ternary oxide of indium (In), tin (Sn), and zinc (Zn). In addition, other oxide semiconductors may include: an In—Al—Zn—O-based semiconductor; an In—Al—Sn—Zn—O-based semiconductor; a Zn—O-based semiconductor; an In—Zn—O-based semiconductor; a Zn—Ti—O-based semiconductor; a Cd—Ge—O-based semiconductor; a Cd—Pb—O-based semiconductor; cadmium oxide (CdO); a Mg—Zn—O-based semiconductor; an In—Ga—Sn—O-based semiconductor; an In—Ga—O-based semiconductor; a Zr—In—Zn—O-based semiconductor; a Hf—In—Zn—O-based semiconductor; an Al—Ga—Zn—O-based semiconductor; a Ga—Zn—O-based semiconductor; an In—Ga—Zn—Sn—O-based semiconductor; InGaO₃(ZnO)₅; zinc magnesium oxide (MgₓZn₁₋ₓO), and zinc cadmium oxide (CdₓZn₁₋ₓO). Note that the Zn—O-based semiconductor may be ZnO doped with one or more kinds of impurity elements among a group 1 element, a group 13 element, a group 14 element, a group 15 element, and a group 17 element. The Zn—O-based semiconductor may be in an amorphous state, in a polycrystalline state, or in a microcrystalline state in which an amorphous state and a polycrystalline state are mixed together. Alternatively. the Zn—O-based semiconductor does not have to be doped with any impurity element.

As illustrated in FIG. 3, the second gate electrode 21a is provided to overlap with the second channel region 19ac of the second semiconductor layer 19a. The second gate electrode 21a controls conduction between the third conductor region 19aa and the fourth conductor region 19ab of the second semiconductor layer 19a. Here, similar to the gate line 21g and the light-emission control line 21e, the second gate electrode 21a is formed of the fourth metal film.

As illustrated in FIG. 3, the third terminal electrode 18c and the fourth terminal electrode 18d are respectively in contact with the third conductive region 19aa and the fourth conductive region 19ab of the second semiconductor layer 19a toward the first interlayer insulating film 17, and respectively and electrically connected to the third conductor region 19aa and the fourth conductor region 19ab of the second semiconductor layer 19a. Here, similar to the first terminal electrode 18a and the second terminal electrode 18b, the third terminal electrode 18c and the fourth terminal electrode 18d are formed of the third metal film.

In this embodiment, a write TFT 9c, a drive TFT 9d, a power-supply TFT 9e, and a light-emission control TFT 9f to be described later are exemplified as the four first TFTs 9A each having the first semiconductor layer 14a formed of polysilicon, and an initialization TFT 9a, a compensation TFT 9b, and an anode-discharge TFT 9g to be described later are exemplified as the three second TFTs 9B each having the second semiconductor layer 19a formed of oxide semiconductor (see FIG. 4). Note that, in the equivalent circuit diagram in FIG. 4, the first terminal electrode 18a and the second terminal electrode 18b of each of the TFTs 9c, 9d, 9e, and Of are denoted by circled numerals 1 and 2, and the third terminal electrode 18c and the fourth terminal electrode 18d of each of the TFTs 9a, 9b, and 9g are denoted by circled numerals 3 and 4. Furthermore, the equivalent circuit diagram in FIG. 4 illustrates a pixel circuit of a subpixel P at the n-th row and the m-th column. The equivalent circuit diagram also partially includes a pixel circuit of a subpixel P at the (n−1)-th row and the m-th column. In addition, in the equivalent circuit diagram in FIG. 4, the power supply line 12g to supply a high power-supply voltage ELVDD also serves as a first initialization power supply line; however, the power supply line 12g and the first initialization power supply line may be provided separately. Moreover, the second initialization power supply line 16i receives, but not limited to, the same voltage as a low power-supply voltage ELVSS. The second initialization power supply line 18i may receive a voltage that differs from the low power-supply voltage ELVSS, and that turns OFF an organic EL element 35 to be described later.

As illustrated in FIGS. 4 and 8, in each subpixel P, the initialization TFT 9a has: the second gate electrode 21a electrically connected to the gate line 21g (n−1) in a preceding stage (n−1-th stage); the third terminal electrode 18c electrically connected to a lower conductive layer of the capacitor 9h, to the third terminal electrode (18c) of the compensation TFT 9b, and to the first gate electrode (16a) of the drive TFT 9d; and the fourth terminal electrode 18d electrically connected to the power supply line 12g.

As illustrated in FIG. 4, in each subpixel P, the compensation TFT 9b has: the second gate electrode (21a) electrically connected to the gate line 21g (n) in the corresponding stage (n-th stage); the third terminal electrode (18c) electrically connected to the lower conductive layer of the capacitor 9h to be described later, to the third terminal electrode (18c) of the initialization TFT 9a, and to the first gate electrode (16a) of the drive TFT 9d; and the fourth terminal electrode (18d) electrically connected to the second terminal electrode (18b) of the power-supply TFT 9e, and to the first terminal electrode (18a) of the drive TFT 9d.

As illustrated in FIGS. 4 and 6, in each subpixel P, the write TFT 9c has: the first gate electrode 16a electrically connected to the gate line 21g (n) in the corresponding stage (n-th stage); the first terminal electrode 18a electrically connected to a corresponding source line 12f; and the second terminal electrode 18b electrically connected to the second terminal electrode (18b) of the drive TFT 9d, and to the first terminal electrode (18a) of the light-emission control TFT 9f.

As illustrated in FIG. 4, in each subpixel P, the drive TFT 9d has: the first gate electrode (16a) electrically connected to the third terminal electrode (18c) of each of the initialization TFT 9a and the compensation TFT 9b, and to the lower conductive layer of the capacitor 9h to be described later; the first terminal electrode (18a) electrically connected to the fourth terminal electrode (18d) of the compensation TFT 9b, and to the second terminal electrode (18b) of the power-supply TFT 9e; and the second terminal electrode (18b) electrically connected to the second terminal electrode (18b) of the write TFT 9c, and to the first terminal electrode (18a) of the light-emission control TFT 9f. Here, the drive TFT 9d controls a drive current of the organic EL element 35.

As illustrated in FIGS. 4 and 7, in each subpixel P, the power-supply TFT 9e has: the first gate electrode 16a electrically connected to the light-emission control line 21e in the corresponding stage (n-th stage); the first terminal electrode 18a electrically connected to the power supply line 12g; and the second terminal electrode 18b electrically connected to the first terminal electrode (18a) of the drive TFT 9d, and to the fourth terminal electrode (18d) of the compensation TFT 9b.

As illustrated in FIGS. 4 and 5, in each subpixel P, the light-emission control TFT 9f has: the first gate electrode 16a electrically connected to the light-emission control line 21e in the corresponding stage (n-th stage); the first terminal electrode 18a electrically connected to the second terminal electrode (18b) of each of the drive TFT 9d and the write TFT 9c; and the second terminal electrode 18b electrically connected through a connection electrode 18j to the third terminal electrode 18c of the anode-discharge TFT 9g, to an upper conductive layer of the capacitor 9h to be described later, and to a first electrode 31 of the organic EL element 35 to be described later.

As illustrated in FIGS. 4 and 5, in each subpixel P, the anode-discharge TFT 9g has: the second gate electrode 21a electrically connected to the gate line 21g (n) in the corresponding stage (n-th stage); the third terminal electrode 18c electrically connected through the connection electrode 18j to the second terminal electrode 18b of the light-emission control TFT 9f, to the upper conductive layer of the capacitor 9h to be described later, and to the first electrode 31 of the organic EL element 35 to be described later; and the fourth terminal electrode 18d electrically connected to the second initialization power supply line 16i.

The capacitor 9h includes, for example: the lower conductive layer (not shown) formed of the second metal film; the first interlayer insulating film 17 provided to cover the lower conductive layer; and the upper conductive layer (not shown) formed of the third metal film, and provided on the first interlayer insulating film 17 to overlap with the lower conductive layer. Moreover, as illustrated in FIG. 4, in each subpixel P, the capacitor 9h has: the lower conductive layer electrically connected to the first gate electrode (16a) of the drive TFT 9d, and to the third terminal electrode (18c) of each of the initialization TFT 9a and the compensation TFT 9b; and the upper conductive layer electrically connected to the third terminal electrode (18c) of the anode-discharge TFT 9g, to the second terminal electrode (18b) of the light-emission control TFT 9f, and to the first electrode 31 of the organic EL element 35 to be described later.

The planarization film 23 has a flat surface in the display region D. The planarization film 23 is made of such a material as, for example, an organic resin material such as polyimide resin or acrylic resin, or a polysiloxane-based spin-on-glass (SOG) material.

As illustrated in FIG. 3, the organic-EL-element layer 40 includes: a plurality of the organic EL elements 35 provided to serve as a plurality of light-emitting elements corresponding to the plurality of subpixels P and arranged in a matrix; and an edge cover 32 provided in a lattice form in common to all the subpixels P to cover a peripheral end portion of the first electrode 31 of each organic EL element 35 to be described later.

As illustrated in FIG. 3, in each subpixel P, the organic EL element 35 includes: the first electrode 31 provided on the planarization film 23 of the TFT layer 30a; an organic EL layer 33 provided on the first electrode 31; and a second electrode 34 provided on the organic EL layer 33.

The first electrode 31 is electrically connected through a contact hole formed in a multilayer film including the second interlayer insulating film 22 and the planarization film 23 to the second terminal electrode 18b of the light-emission control TFT 9f for each subpixel P. Furthermore, the first electrode 31 has a function of injecting holes into the organic EL layer 33. Moreover, the first electrode 31 is preferably formed of a material having a large work function to improve efficiency in injecting the holes into the organic EL layer 33. Here, examples of the material forming the first electrode 31 include metal materials such as silver (Ag), aluminum (Al), vanadium (V), cobalt (Co), nickel (Ni), tungsten (W), gold (Au), titanium (Ti), ruthenium (Ru), manganese (Mn), indium (In), ytterbium (Yb), lithium fluoride (LiF), platinum (Pt), palladium (Pd), molybdenum (Mo), iridium (Ir), and tin (Sn). In addition, the first electrode 31 may be made of, for example, an alloy of astatine (At)/astatine oxide (AtO₂). Furthermore, the first electrode 31 may be made of a conductive oxide such as, for example, tin oxide (SnO), zinc oxide (ZnO), indium tin oxide (ITO), or indium zinc oxide (IZO). Moreover, the first electrode 31 may be formed of a plurality of layers made of the above materials and stacked on top of another. Note that examples of compound materials having a large work function include indium tin oxide (ITO) and indium zinc oxide (IZO).

As illustrated in FIG. 9, the organic EL layer 33 includes: a hole injection layer 1; a hole transport layer 2; a light-emitting layer 3, an electron transport layer 4, and an electron injection layer 5, all of which are provided in the stated order above the first electrode 31.

The hole injection layer 1 is also referred to as an anode buffer layer. The hole injection layer 1 has a function of approximating energy levels between the first electrode 31 and the organic EL layer 33 to improve efficiency in injecting the holes from the first electrode 31 into the organic EL layer 33. Here, examples of a material forming the hole injection layer 1 include a triazole derivative, an oxadiazole derivative, an imidazole derivative, a polyarylalkane derivative, a pyrazoline derivative, a phenylenediamine derivative, an oxazole derivative, a styrylanthracene derivative, a fluorenone derivative, a hydrazone derivative, and a stilbene derivative.

The hole transport layer 2 has a function of improving efficiency in transporting the holes from the first electrode 31 to the organic EL layer 33. Here, examples of a material forming the hole transport layer 2 include a porphyrin derivative, an aromatic tertiary amine compound, a styrylamine derivative, polyvinyl carbazole, poly-p-phenylenevinylene, polysilane, a triazole derivative, an oxadiazole derivative, an imidazole derivative, a polyarylalkane derivative, a pyrazoline derivative, a pyrazolone derivative, a phenylenediamine derivative, an arylamine derivative, an amine-substituted chalcone derivative, an oxazole derivative, a styrylanthracene derivative, a fluorenone derivative, a hydrazone derivative, a stilbene derivative, hydrogenated amorphous silicon, hydrogenated amorphous silicon carbide, zinc sulfide, zinc selenide, and zinc selenide.

The light-emitting layer 3 is a region where the holes and the electrons are respectively injected from the first electrode 31 and the second electrode 34, and recombine together, when a voltage is applied with the first electrode 31 and the second electrode 34. Here, the light-emitting layer 3 is formed of a material having high light-emission efficiency. Examples of the material forming the light-emitting layer 3 include a metal oxinoid compound [8-hydroxyquinoline metal complex], a naphthalene derivative, an anthracene derivative, a diphenylethylene derivative, a vinylacetone derivative, a triphenylamine derivative, a butadiene derivative, a coumarin derivative, a benzoxazole derivative, an oxadiazole derivative, an oxazole derivative, a benzimidazole derivative, a thiadiazole derivative, a benzothiazole derivative, a styryl derivative, a styrylamine derivative, a bisstyrylbenzene derivative, a trisstyrylbenzene derivative, a perylene derivative, a perinone derivative, an aminopyrene derivative, a pyridine derivative, a rhodamine derivative, an aquizine derivative, phenoxazone, a quinacridone derivative, rubrene, poly-p-phenylenevinylene, and polysilane.

The electron transport layer 4 has a function of efficiently moving the electrons to the light-emitting layer 3. Here, examples of a material forming the electron transport layer 4 include, as organic compounds, an oxadiazole derivative, a triazole derivative, a benzoquinone derivative, a naphthoquinone derivative, an anthraquinone derivative, a tetracyanoanthraquinodimethane derivative, a diphenoquinone derivative, a fluorenone derivative, a silole derivative, and a metal oxinoid compound.

The electron injection layer 5 has a function of approximating energy levels between the second electrode 34 and the organic EL layer 33 to improve efficiency in injecting the electrons from the second electrode 34 into the organic EL layer 33. Such a function can decrease a drive voltage of the organic EL element 35. Note that the electron injection layer 5 is also referred to as a cathode buffer layer. Here, examples of a material forming the electron injection layer 5 include: inorganic alkali compounds such as lithium fluoride (LiF), magnesium fluoride (MgF₂), calcium fluoride (CaF₂), strontium fluoride (SrF₂), and barium fluoride (BaF₂); aluminum oxide (Al₂O₃); and strontium oxide (SrO).

As illustrated in FIG. 3, the second electrode 34 is provided in common to all the subpixels P to cover each organic EL layer 33 and the edge cover 32. Moreover, the second electrode 34 has a function of injecting the electrons into the organic EL layer 33. Furthermore, the second electrode 34 is preferably formed of a material having a small work function to improve efficiency in injecting the electrons into the organic EL layer 33. Here, examples of the material forming the second electrode 34 include silver (Ag), aluminum (Al), vanadium (V), calcium (Ca), titanium (Ti), yttrium (Y), sodium (Na), manganese (Mn), indium (In), magnesium (Mg), lithium (Li), ytterbium (Yb), and lithium fluoride (LiF). Moreover, the second electrode 34 may be formed of an alloy such as magnesium (Mg)/copper (Cu), magnesium (Mg)/silver (Ag), sodium (Na)/potassium (K), astatine (At)/astatine oxide (AtO₂), lithium (Li)/aluminum (Al), lithium (Li)/calcium (Ca)/aluminum (Al), or lithium fluoride (LiF)/calcium (Ca)/aluminum (Al). Furthermore, the second electrode 34 may be formed of a conductive oxide such as tin oxide (SnO), zinc oxide (ZnO), indium tin oxide (ITO), or indium zinc oxide (IZO). In addition, the second electrode 34 may be formed of a plurality of layers made of the above materials and stacked on top of another. Note that examples of the material having a small work function include magnesium (Mg), lithium (Li), lithium fluoride (LiF), magnesium (Mg)/copper (Cu), magnesium (Mg)/silver (Ag), sodium (Na)/potassium (K), lithium (Li)/aluminum (Al), lithium (Li)/calcium (Ca)/aluminum (Al), and lithium fluoride (LiF)/calcium (Ca)/aluminum (Al).

The edge cover 32 is made of, for example, an organic resin material such as polyimide resin or acrylic resin, or a polysiloxane-based SOG material.

As illustrated in FIG. 3, the sealing film 45 is provided to cover the second electrode 34, and includes: a first inorganic sealing film 41; an organic sealing film 42; and a second inorganic sealing film 43, all of which are sequentially stacked on top of another above the second electrode 34. The sealing film 45 has a function of protecting the organic EL layer 33 in the organic EL element 35 from moisture and oxygen.

Each of the first inorganic sealing film 41 and the second inorganic sealing film 43 is formed of such an inorganic insulating film as, for example, a silicon nitride film, a silicon oxide film, or a silicon oxynitride film.

The organic sealing film 42 is formed of such an organic resin material as, for example, acrylic resin, epoxy resin, silicone resin, polyurea resin, parylene resin, polyimide resin, or polyamide resin.

As to the organic EL display device 50a having the above configuration, in each subpixel P, when the light-emission control line 21e is first selected to be in an inactive state, the organic EL element 35 is in a non-light-emission state. In the non-light-emission state, the gate line 21g (n−1) in the preceding stage is selected. Through the gate line 21g (n−1), a gate signal is input into the initialization TFT 9a such that the initialization TFT 9a turns ON. Hence, the high power-supply voltage ELVDD of the power supply line 12g is applied to the capacitor 9h, and the drive TFT 9d turns ON. Thus, charges of the capacitor 9h are discharged, and a voltage to be applied to the gate electrode of the drive TFT 9d is initialized. Next, when the gate line 21g (n) of the corresponding stage is selected to be in the active state, the compensation TFT 9b and the write TFT 9c turn ON, and a predetermined voltage corresponding to a source signal to be transmitted through the corresponding source line 12f is written into the capacitor 9h through the drive TFT 9d connected to a diode. Simultaneously, the anode-discharge TFT 9g turns ON, and an initialization signal is applied through the second initialization power supply line 19i to the first electrode 31 of the organic EL element 35. Hence, the charges stored in the first electrode 31 are reset. After that, the light-emission control line 21e is selected, and the power-supply TFT 9e and the light-emission control TFT 9f turn ON. Hence, a drive current corresponding to the voltage applied to the gate electrode of the drive TFT 9d is supplied from the power supply line 12g to the organic EL element 35. Thus, in each subpixel P, the organic EL element 35 emits light the luminance of which corresponds to the drive current. This is how the organic EL display device 50a displays an image.

Described next will be a method for producing the organic EL display device 50a of this embodiment. Note that the method for producing the organic EL display device 50a includes: a TFT-layer forming step; an organic-EL-element-layer forming step; and a sealing-film forming step.

### TFT-Layer Forming Step

First, for example, such a film as a silicon oxide film (approximately 150 nm in thickness) is deposited by, for example, plasma chemical vapor deposition (CVD) on the resin substrate 10 formed on a glass substrate. Hence, the first base coat film 11 is formed.

Next, on the substrate surface provided with the first base coat film 11, such a film as a molybdenum film (approximately 250 nm in thickness) is deposited by, for example, sputtering to form the first metal film. After that, the first metal film is patterned to form such constituent features as the lower light-blocking layer 12a, the source line 12f, and the power supply line 12g.

Furthermore, on the substrate surface provided with such a constituent feature as the lower light-blocking layer 12a, such a film as a silicon oxide film (approximately 300 nm in thickness) is deposited by, for example, the plasma CVD to form the second base coat film 13.

After that, on the substrate surface provided with the second base coat film 13, an amorphous silicon film (approximately 50 nm in thickness) is deposited by, for example, the plasma CVD. The amorphous silicon film is crystallized by such a technique as laser annealing to form the first semiconductor film formed of polysilicon. After that, the first semiconductor film is patterned to form the first semiconductor layer 14a.

Subsequently, on the substrate surface provided with the first semiconductor layer 14a, such a film as a silicon oxide film (approximately 125 nm in thickness) is deposited by, for example, the plasma CVD to form the first gate insulating film 15. After that, such a film as a molybdenum film (approximately 200 nm in thickness) is deposited by, for example, sputtering to form the second metal film. The second metal film is patterned to form such constituent features as the first gate electrode 16a and the second initialization power supply line 16i.

Moreover, using the first gate electrode 16a as a mask, the first semiconductor layer 14a is doped with such impurity ions as, for example, phosphorus so that a portion of the first semiconductor layer 14a becomes conductive to form the first conductor region 14aa, the second conductor region 14ab, and the first channel region 14ac in the first semiconductor layer 14a.

After that, on the substrate surface of the conductive portion in the first semiconductor layer 14a, a silicon nitride film (approximately 150 nm in thickness) and a silicon oxide film (approximately 50 nm in thickness) are sequentially deposited by, for example, the plasma CVD. After that, contact holes are formed in a multilayer film including the silicon nitride film and the silicon oxide film. Hence, the first interlayer insulating film 17 is formed.

Subsequently, on the substrate surface provided with the first interlayer insulating film 17, such films as a titanium film (approximately 50 nm in thickness), a copper film (approximately 400 nm in thickness), and an ITO film (approximately 50 nm in thickness) are deposited in the stated order by, for example, sputtering to form the third metal film. After that, the third metal film is patterned to form such constituent features as the first terminal electrode 18a, the second terminal electrode 18b, the third terminal electrode 18c, and the fourth terminal electrode 18d.

Furthermore, on the substrate surface provided with such a constituent feature as the first terminal electrode 18a, an oxide semiconductor film (approximately 30 nm in thickness) such as an InGaZnO₄ film is deposited by, for example, sputtering to form the second semiconductor film. After that, the second semiconductor film is patterned to form the second semiconductor layer 19a.

After that, on the substrate surface provided with the second semiconductor layer 19a, such a film as a silicon oxide film (approximately 100 nm in thickness) is deposited by, for example, the plasma CVD. After that, such a film as a molybdenum film (approximately 200 nm in thickness) is deposited by, for example, sputtering to form the fourth metal film. After that, the silicon oxide film is patterned to form the second gate insulating film 20, and the fourth metal film is patterned to form such constituent features as the second gate electrode 21a, the gate line 21g, and the light-emission control line 21e.

Subsequently, on the substrate surface provided with such a constituent feature as the second gate insulating film 20, such a film as a silicon oxide film (approximately 500 nm in thickness) is deposited by, for example, the plasma CVD to form the second interlayer insulating film 22. Note that, by heat treatment after the formation of the second interlayer insulating film 22, a portion of the second semiconductor layer 19a becomes conductive to form the third conductor region 19aa, the fourth conductor region 19ab, and the second channel region 19ac in the second semiconductor layer 19a.

Furthermore, the substrate surface provided with the second interlayer insulating film 22 is coated with an acrylic-based photosensitive resin film (approximately 2 μm in thickness) by, for example, spin coating or slit coating. After that, the coating film is pre-baked, exposed to light, developed, and post-baked to form the planarization film 23 having a contact hole.

Finally, the second interlayer insulating film 22 exposed from the contact hole of the planarization film 23 is removed, so that the contact hole reaches the second terminal electrode 18b of the light-emission control TFT 9f.

As described above, the TFT layer 30a is successfully formed.

### Organic-EL-Element-Layer Forming Step

On the planarization film 23 of the TFT layer 30a formed at the TFT-layer forming step, the first electrode 31, the edge cover 32, the organic EL layer 33 (including the hole injection layer 1, the hole transport layer 2, the light-emitting layer 3, the electron transport layer 4, and the electron injection layer 5), and the second electrode 34 are formed, using a known technique. Hence, the organic-EL-element layer 40 is formed.

### Sealing-Film Forming Step

First, on a substrate surface of the organic-EL-element layer 40 formed at the organic-EL-element-layer forming step, an inorganic insulating film such as, for example, a silicon nitride film, a silicon oxide film, or a silicon oxynitride film is deposited by the plasma CVD, using a mask. Hence, the first inorganic sealing film 41 is formed.

Then, on a substrate surface of the first inorganic sealing film 41, for example, an organic resin material such as acrylic resin is deposited by inkjet printing. Hence, the organic sealing film 42 is formed.

After that, on the substrate surface provided with the organic sealing film 42, an inorganic insulating film such as, for example, a silicon nitride film, a silicon oxide film, or a silicon oxynitride film is deposited by the plasma CVD, using a mask, to form the second inorganic sealing film 43. Hence, the sealing film 45 is formed.

Finally, a protective sheet (not shown) is attached to the substrate surface provided with the sealing film 45. After that, a laser beam is emitted from toward the glass substrate of the resin substrate 10, and the glass substrate is removed from a lower surface of the resin substrate 10. To the lower surface of the resin substrate 10 from which the glass substrate is removed, a protective sheet (not shown) is attached.

As can be seen, the organic EL display device 50a of this embodiment is successfully produced.

As described above, in the organic EL display device 50a of this embodiment, each of the subpixels P includes second TFTs 9B having the respective second semiconductor layers 19a made of oxide semiconductor. In each of the second TFTs 9B, the third terminal electrode 18c and the fourth terminal electrode 18d are respectively in contact from toward the resin substrate 10 with, and electrically connected to, the third conductor region 19aa and the fourth conductor region 19ab of the second semiconductor layer 19a. Thus, in order to establish electrical connection to the third conductor region 19aa and the fourth conductor region 19ab of the second semiconductor layer 19a, for example, contact holes may be formed either toward the organic-EL-element layer 40 or toward the resin substrate 10 in relation to the third terminal electrode 18c and the fourth terminal electrode 18d in order to reach the third terminal electrode 18c and the fourth terminal electrode 18d, instead of forming contact holes reaching the third conductor region 19aa and the fourth conductor region 19ab made of oxide semiconductor poorly resistant to such a substance as hydrofluoric acid. Such a feature can readily establish electrical connection to the second semiconductor layer 19a made of oxide semiconductor. Furthermore, in the TFT layer 30a, the first base coat film 11, the first metal film, the second base coat film 13, the first semiconductor film made of polysilicon, the first gate insulating film 15, the second metal film, the first interlayer insulating film 17, the third metal film, the second semiconductor film made of oxide semiconductor, the second gate insulating film 20, and the fourth metal film are sequentially stacked on top of another above the resin substrate 10. In the display region (D), the plurality of source lines 12f and the plurality of power supply lines 12g formed of the first metal film are provided to extend in parallel with one another. As a result, a gate line 21g and a light-emission control line 21e formed of the fourth metal film are spaced apart from a source line 12f and a power supply line 12g in the thickness direction. Such a feature can reduce wiring cross capacitance between: the gate line 21g and the light-emission control line 21e; and the source line 12f and the power supply line 12g. Hence, the feature can readily establish electrical connection to a semiconductor layer made of oxide semiconductor, and simultaneously reduce wiring cross capacitance.

Moreover, in the organic EL display device 50a of this embodiment, the source line 12f and the power supply line 12g are formed of the first metal film, and the first terminal electrode 18a and the second terminal electrode 18b of each first TFT 9A, and the third terminal electrode 18c and the fourth terminal electrode 18d of each second TFT 9B are formed of the third metal film. Hence, the source line 12f, the power supply line 12g, the first terminal electrode 18a, the second terminal electrode 18b, the third terminal electrode 18c, and the fourth terminal electrode 18d are provided in different layers from one another. Thus, the wires extending to the display region D and the electrodes of the first TFTs 9A and the second TFTs 9B in each subpixel P of the display region D are formed in separate layers. Such a feature can reduce wiring leakage between the source line 12f and the power supply line 12g adjacent to each other even for a size of high-definition pixels to be used for, for example, a mobile device.

In addition, in the organic EL display device 50a of this embodiment, the lower light-blocking layer 12a formed of the first metal film is provided to the second semiconductor layer 19a toward the resin substrate 10. Such a feature can block light from entering the second channel region 19ac of the second semiconductor layer 19a and impurity ions contained in the resin substrate 10 from reaching the second channel region 19ac.

### Second Embodiment

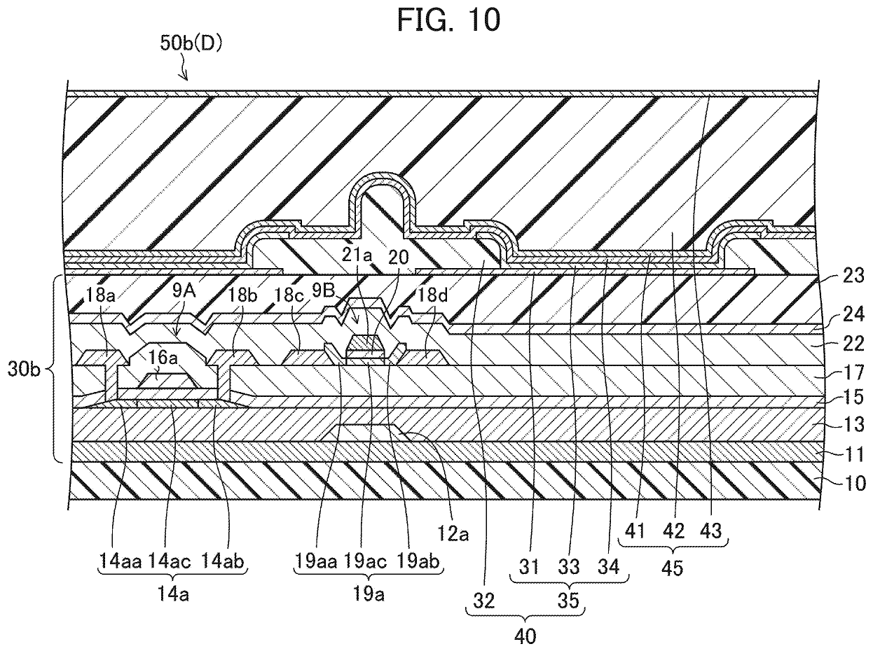

FIG. 10 illustrates a second embodiment of the display device according to the present disclosure. Here, FIG. 10 is a cross-sectional view of the display region D of an organic EL display device 50b of this embodiment. Note that, in the embodiment below, like reference signs seen in FIGS. 1 to 9 designate identical constituent features. These constituent features will not be elaborated upon here.

The first embodiment exemplifies the organic EL display device 50a including the TFT layer 30a provided with the lower light-blocking layer 12a. This embodiment exemplifies the organic EL display device 50b including a TFT layer 30b provided with the lower light-blocking layer 12a and an upper light-blocking layer 24.

Similar to the organic EL display device 50a of the first embodiment, the organic EL display device 50b includes, for example: the display region D shaped into a rectangle and displaying an image; and the picture-frame region F provided around the display region D.

As illustrated in FIG. 10, the organic EL display device 50b includes: the resin substrate 10 provided as a base substrate; a TFT layer 30b provided on the resin substrate 10; the organic-EL-element layer 40 provided on the TFT layer 30b to serve as a light-emitting-element layer; and the sealing film 45 provided on the organic-EL-element layer 40.

Similar to the TFT layer 30a of the first embodiment, the TFT layer 30b illustrated in FIG. 10 includes: the first base coat film 11 and the second base coat film 13 sequentially provided above the resin substrate 10; four first TFTs 9A, three second TFTs 9B, and one capacitor 9h all of which are provided on the second base coat film 13 for each of the subpixels P (see FIG. 4); and the second interlayer insulating film 22 and the planarization film 23 sequentially provided above each of the first TFTs 9A, the second TFTs 9B, and the capacitor 9h. Here, similar to the TFT layer 30a of the first embodiment, the TFT layer 30b includes the plurality of gate lines 21g, the plurality of light-emission control lines 21e, the plurality of second initialization power supply lines 16i, the plurality of source lines 12f, and the plurality of power supply lines 12g.

The TFT layer 30b illustrated in FIG. 10 includes: the first base coat film 11; the first metal film; the second base coat film (the first inorganic insulating film) 13; the first semiconductor film; the first gate insulating film (the second inorganic insulating film) 15; the second metal film; the first interlayer insulating film (the third inorganic interlayer insulating film) 17; the third metal film; the second semiconductor film; the second gate insulating film (the fourth inorganic insulating film) 20; the fourth metal film; the second interlayer insulating film (the fifth inorganic insulating film) 22; a fifth metal film; and the planarization film 23, all of which are sequentially stacked on top of another above the resin substrate 10. Here, in the TFT layer 30b, as illustrated in FIG. 10, the upper light-blocking layer 24 formed of the fifth metal film is provided to the first TFT 9A and the second TFT 9B toward the organic-EL-element layer 40. Note that the upper light-blocking layer 24 is provided to overlap with the first semiconductor layer 14a of the first TFT 9A and the second semiconductor layer 19a of the second TFT 9B in a plan view.

The organic EL display device 50b in the above configuration is similar to the organic EL display device 50a of the first embodiment. In each subpixel P, the organic EL element 35 emits light the luminance of which corresponds to the drive current. This is how the organic EL display device 50b displays an image.

The organic EL display device 50b of this embodiment can be produced as follows: at the TFT-layer forming step in the method for producing the organic EL display device 50a of the first embodiment, such a film as a molybdenum film (approximately 250 nm in thickness) is deposited on a substrate surface provided with the second interlayer insulating film 22 by, for example, sputtering to form the fifth metal film. After that, the fifth metal film is patterned to form the upper light-blocking layer 24. Furthermore, as seen in the first embodiment, the planarization film 23 is formed so that the TFT layer 30b is formed. Hence, the organic EL display device 50b is successfully produced.

As described above, in the organic EL display device 50b of this embodiment, each of the subpixels P includes second TFTs 9B having the respective second semiconductor layers 19a made of oxide semiconductor. In each of the second TFTs 9B, the third terminal electrode 18c and the fourth terminal electrode 18d are respectively in contact from toward the resin substrate 10 with, and electrically connected to, the third conductor region 19aa and the fourth conductor region 19ab of the second semiconductor layer 19a. Thus, in order to establish electrical connection to the third conductor region 19aa and the fourth conductor region 19ab of the second semiconductor layer 19a, for example, contact holes may be formed either toward the organic-EL-element layer 40 or toward the resin substrate 10 in relation to the third terminal electrode 18c and the fourth terminal electrode 18d in order to reach the third terminal electrode 18c and the fourth terminal electrode 18d, instead of forming contact holes reaching the third conductor region 19aa and the fourth conductor region 19ab made of oxide semiconductor poorly resistant to such a substance as hydrofluoric acid. Such a feature can readily establish electrical connection to the second semiconductor layer 19a made of oxide semiconductor. Furthermore, in the TFT layer 30b, the first base coat film 11, the first metal film, the second base coat film 13, the first semiconductor film made of polysilicon, the first gate insulating film 15, the second metal film, the first interlayer insulating film 17, the third metal film, the second semiconductor film made of oxide semiconductor, the second gate insulating film 20, and the fourth metal film are sequentially stacked on top of another above the resin substrate 10. In the display region (D), the plurality of source lines 12f and the plurality of power supply lines 12g formed of the first metal film are provided to extend in parallel with one another. As a result, a gate line 21g and a light-emission control line 21e formed of the fourth metal film are spaced apart from a source line 12f and a power supply line 12g in the thickness direction. Such a feature can reduce wiring cross capacitance between: the gate line 21g and the light-emission control line 21e; and the source line 12f and the power supply line 12g. Hence, the feature can readily establish electrical connection to a semiconductor layer made of oxide semiconductor, and simultaneously reduce wiring cross capacitance.

Moreover, in the organic EL display device 50b of this embodiment, the source line 12f and the power supply line 12g are formed of the first metal film, and the first terminal electrode 18a and the second terminal electrode 18b of each first TFT 9A, and the third terminal electrode 18c and the fourth terminal electrode 18d of each second TFT 9B are formed of the third metal film. Hence, the source line 12f, the power supply line 12g, the first terminal electrode 18a, the second terminal electrode 18b, the third terminal electrode 18c, and the fourth terminal electrode 18d are provided in different layers from one another. Thus, the wires extending to the display region D and the electrodes of the first TFTs 9A and the second TFTs 9B in each subpixel P of the display region D are formed in separate layers. Such a feature can reduce wiring leakage between the source line 12f and the power supply line 12g adjacent to each other even for a size of high-definition pixels to be used for, for example, a mobile device.

In addition, in the organic EL display device 50b of this embodiment, the lower light-blocking layer 12a formed of the first metal film is provided to the second semiconductor layer 19a toward the resin substrate 10. Such a feature can block light from entering the second channel region 19ac of the second semiconductor layer 19a and impurity ions contained in the resin substrate 10 from reaching the second channel region 19ac.

Furthermore, in the organic EL display device 50b of this embodiment, the upper light-blocking layer 24 is provided to the first TFTs 9A and the second TFTs 9B toward the organic-EL-element layer 30. Even if light emitted from the organic EL element 35 strays, the stray light is less likely to enter the first semiconductor layer 14a of each first TFT 9A and the second semiconductor layer 19a of each second TFT 9B such that the first TFT 9A and the second TFT 9B can operate with further stability.

### Other Embodiments

The above embodiments exemplify organic EL display devices each including, in a subpixel in the display region, a first TFT having the first semiconductor layer formed of polysilicon and a second TFT having the second semiconductor layer formed of oxide semiconductor. Alternatively, the first TFT may be provided to the picture-frame region to form a driver circuit such as a gate driver.

Moreover, in each of the above embodiments, the exemplified organic EL layer has a multilayer structure including five layers such as a hole injection layer, a hole transport layer, a light-emitting layer, an electron transport layer, and an electron injection layer. Alternatively, the organic EL layer may have a multilayer structure including three layers such as, for example, a hole-injection-and-hole-transport layer, a light-emitting layer, and an electron-transport-and-electron-injection layer.

Moreover, in each of the above embodiments, the exemplified organic EL display device includes a first electrode as an anode and a second electrode as a cathode. The present disclosure can also be applied to an organic EL display device whose multilayer structure of the organic EL layer is inverted, such that the first electrode is a cathode and the second electrode is an anode.

In addition, in the above embodiment, the organic EL display device is exemplified as a display device. The present disclosure can be applied to a display device including a plurality of light-emitting elements driven by currents. For example, the present disclosure can be applied to a display device including quantum-dot light-emitting diodes (QLEDs); that is, light-emitting elements including layers containing quantum dots.

### INDUSTRIAL APPLICABILITY

As described above, the present disclosure is useful for a flexible display device.

1. A display device, comprising:
a base substrate; and
a thin-film transistor layer provided on the base substrate and including: a first metal film; a first inorganic insulating film; a first semiconductor film made of polysilicon; a second inorganic insulating film; a second metal film; a third inorganic insulating film; a third metal film; a second semiconductor film made of oxide semiconductor; a fourth inorganic insulating film; and a fourth metal film, all of which are sequentially stacked on top of another,
wherein the thin-film transistor layer includes: a first thin-film transistor having a first semiconductor layer formed of the first semiconductor film; and a second thin-film transistor having a second semiconductor layer formed of the second semiconductor film, the first thin-film transistor and the second thin-film transistor being provided for each of subpixels included in a display region,
the first thin-film transistor includes: the first semiconductor layer; a first gate electrode; and a first terminal electrode and a second terminal electrode, the first semiconductor layer including: a first conductor region and a second conductor region defined to be spaced apart from each other; and a first channel region defined between the first conductor region and the second conductor region, the first gate electrode being formed of the second metal film and provided above the first semiconductor layer through the second inorganic insulating film, and the first terminal electrode and the second terminal electrode being formed of the third metal film, spaced apart from each other, and respectively and electrically connected to the first conductor region and the second conductor region,
the second thin-film transistor includes: the second semiconductor layer; a second gate electrode; and a third terminal electrode and a fourth terminal electrode, the second semiconductor layer including: a third conductor region and a fourth conductor region defined to be spaced apart from each other; and a second channel region defined between the third conductor region and the fourth conductor region, the second gate electrode being formed of the fourth metal film and provided above the second semiconductor layer through the fourth inorganic insulating film, and the third terminal electrode and the fourth terminal electrode being formed of the third metal film, spaced apart from each other, and respectively and electrically connected to the third conductor region and the fourth conductor region, and
the display region is provided with a plurality of wires formed of the first metal film and extending in parallel with one another.

2. The display device according to claim 1,
wherein the wires are either source lines or power supply lines.

3. The display device according to claim 1, further comprising
a lower light-blocking layer formed of the first metal film and provided to the second semiconductor layer toward the base substrate.

4. The display device according to claim 1,
wherein the thin-film transistor layer includes: a fifth inorganic insulating film; and a planarization film made of an organic resin material, both of which are sequentially stacked on top of another above the fourth metal film.

5. The display device according to claim 4, further comprising:
a light-emitting-element layer provided on the thin-film transistor layer and including a plurality of light-emitting elements arranged in association with a plurality of subpixels included in the display region; and
a sealing film provided on the light-emitting-element layer.

6. The display device according to claim 5, further comprising:
a fifth metal film provided between the fifth inorganic insulating film and the planarization film; and
an upper light-blocking layer formed of the fifth metal film and provided to the first thin-film transistor and the second thin-film transistor toward the light-emitting-element layer.

7. The display device according to claim 5,
wherein the light-emitting elements are organic electroluminescent elements.
